(19) United States
(12) Patent Application Publication
(10) Pub. No.: US 2026/0173245 A1
(43) Pub. Date: Jun. 18, 2026

(54) SUBSTRATE PROCESSING DEVICE

(71) Applicant: SAMSUNG ELECTRONICS CO., LTD., Suwon-si (KR)

(72) Inventors: Eunsook PARK, Suwon-si (KR); Junho IM, Suwon-si (KR); Jisoo IM, Suwon-si (KR); Manick HA, Suwon-si (KR); Woohyun KIM, Suwon-si (KR)

(73) Assignee: SAMSUNG ELECTRONICS CO., LTD., Suwon-si (KR)

(21) Appl. No.: 19/252,674

(22) Filed: Jun. 27, 2025

(30) Foreign Application Priority Data
Dec. 16, 2024 (KR) 10-2024-0187566

(51) Int. Cl. H05H 3/06; G03F 7/36; H01J 37/32

(52) U.S. Cl. CPC H05H 3/06; G03F 7/36; H01J 37/32357; H01J 37/32724; H01J 2237/24585

(57) ABSTRACT

A substrate processing device includes a plasma chamber, a power voltage source, a process chamber, a grid structure, and a reflector. The power voltage source is arranged in the plasma chamber for generating plasma. The process chamber defines a processing region for processing a substrate, and arranged below the plasma chamber. The grid structure is arranged between the process chamber and the plasma chamber for receiving the plasma and supplying ions or radicals to the substrate The reflector is for forming neutrons from the ions or the radicals and supplying the neutrons to the substrate.

### CROSS-REFERENCE TO RELATED APPLICATION

This application claims priority to and the benefit of Korean Patent Application No. 10-2024-0187566 filed with the Korean Intellectual Property Office on Dec. 16, 2024, the entire contents of which are incorporated herein by reference.

### BACKGROUND OF THE INVENTION

### (a) Field of the Invention

The present disclosure relates to a substrate processing device. More particularly, the present disclosure relates to a substrate processing device for forming a pattern on a substrate.

### (b) Description of the Related Art

Manufacturing of semiconductor devices such as ICs is a multi-step process involving photolithography. In general, the process includes depositing a material onto a wafer and patterning the material using lithographic techniques to form a semiconductor device. A wet developing method was used as a method for etching the semiconductor pattern.

In detail, the wet developing method proceeds in order of spraying a solution onto a material such as a substrate using a spinner and then applying a spin. Affinity between the photoresist and the developer is used to melt the exposed or non-exposed area, and the developer is cleaned and dried by spraying DI water.

However, the wet developing method has a problem in that swelling occurs due to the difference in interface resistance between the exposed and non-exposed areas during the rinse process, and defects such as blobs occur after the swelling. The wet developing method has a problem in that the pattern collapses due to surface tension.

To overcome these problems, a dry developing method is being utilized. In detail, the dry developing method of plasma etching using plasma is widely used as a pattern etching method for finely patterning semiconductor circuits due to the miniaturization and higher integration of semiconductors. The plasma etching etches an etching target by forming plasma and reacting ions and radicals generated from the plasma with a target material.

As an example of the dry developing method, a dry developing method using halogen-based developing chemical materials is being utilized. However, the dry developing method has a problem in that it forms a volatility material, R—Sn—X (X=Br or CI), as a reaction product, which contaminates the FOUP or the line of the subsequent movement process. The dry developing method has a problem in that it uses highly reactive halogen elements, which react with the chamber materials, ceramic and metal, thereby corroding the chamber and generating particles. The dry developing method is progressed in a pseudo-isotropic way by chemical reactions so it causes roughness and damages to line patterns.

### SUMMARY OF THE INVENTION

The present disclosure provides a substrate processing device for preventing contamination caused by by-products generated by performing a dry development, and preventing damages of pattern lines with an anisotropic development.

The present disclosure provides a substrate processing method for preventing contamination caused by by-products generated by performing a dry development, and preventing damages of pattern lines with an anisotropic development.

An embodiment of the present disclosure provides a substrate processing device including: a plasma chamber; a power voltage source arranged in the plasma chamber for generating plasma; a process chamber defining a processing region for processing a substrate, and arranged below the plasma chamber; a grid structure arranged between the process chamber and the plasma chamber for receiving the plasma and supplying ions or radicals; and a reflector for forming neutrons from the ions or the radicals and supplying the neutrons to the substrate.

Another embodiment of the present disclosure provides a substrate processing device including: a plasma chamber; a power voltage source arranged in the plasma chamber for generating plasma; a process chamber defining a processing region for processing a substrate, and arranged below the plasma chamber; a grid structure arranged between the process chamber and the plasma chamber for receiving the plasma and supplying ions or radicals; and a reflector for forming neutrons from the ions or the radicals and supplying the neutrons to the substrate, wherein the grid structure includes a first grid arranged near the plasma chamber and a second grid arranged below the first grid, and the first grid is configured to receive a higher voltage than the second grid.

Another embodiment of the present disclosure provides a substrate processing device including: a plasma chamber; a power voltage source arranged in the plasma chamber for generating plasma; a substrate supporting unit for supporting a substrate; a process chamber defining a processing region for processing the substrate, and arranged below the plasma chamber; a grid structure arranged between the process chamber and the plasma chamber for receiving the plasma and supplying ions or radicals, and including a first grid arranged near the plasma chamber and a second grid arranged below the first grid; a reflector for forming neutrons from the ions or the radicals and supplying the neutrons to the substrate; and a heating member connected to the substrate supporting unit and heating the substrate, wherein the voltage supplied to the first grid and the voltage supplied to the second grid satisfy Condition 1:

$$\vert {G}_{1} - {G}_{2} \vert \geq 600 V \qquad 〈 Condition 1 〉$$

here, G₁ and G₂ represent the voltage supplied to the first grid and the voltage supplied to the second grid, and |G₁-G₂| represents an absolute value of a difference value between the voltages G₁ and G₂.

According to the embodiment of the present disclosure, the substrate processing device includes a grid structure and a reflector to form neutral beams including neutrons, thereby preventing contamination due to the by-products generated during the dry development and preventing damages to the pattern lines due to anisotropic development, thereby improving the reliability of substrate processing.

According to the embodiment of the present disclosure, the substrate processing device may control the difference of the etch rates according to the density of photoresist by using an inert gas and controlling the voltage applied to a grid structure, thereby easily and selectively removing unexposed photoresist and improving the reliability of substrate processing.

### BRIEF DESCRIPTION OF THE DRAWINGS

FIG. 1 shows a schematic view illustrating a substrate processing system according to an embodiment of the present disclosure.

FIG. 2 shows a cross-sectional view illustrating a substrate processing device with respect to a line A-A′ of FIG. 1 according to an embodiment of the present disclosure.

FIG. 3 shows an enlarged view on a region P1 of FIG. 2.

FIG. 4 and FIG. 5 show top plan views of a reflector according to an embodiment of the present disclosure.

FIG. 6 to FIG. 8 show cross-sectional views illustrating a substrate processing device according to another embodiment of the present disclosure.

FIG. 9 shows a flowchart illustrating a substrate processing method using a substrate processing device according to the present disclosure, and FIG. 10 to FIG. 13 show the substrate processing method.

FIG. 14 and FIG. 15 show enlarged regions P2 and P3 of FIG. 12.

FIG. 16 shows a flowchart illustrating a substrate processing method according to another embodiment of the present disclosure.

FIG. 17 to FIG. 18 show a sequence of a substrate processing method according to an embodiment of the present disclosure, and FIG. 19 and FIG. 20 show graphs illustrating etch amounts and etch rates according to the substrate processing method.

### DETAILED DESCRIPTION OF THE EMBODIMENTS

The present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

The drawings and description are to be regarded as illustrative in nature and not restrictive, and like reference numerals designate like elements throughout the specification.

The size and thickness of each configuration shown in the drawings are arbitrarily shown for better understanding and ease of description, but the present disclosure is not limited thereto. In the drawings, the thickness of layers, films, panels, regions, etc., are enlarged for clarity. The thicknesses of some layers and areas are exaggerated for convenience of explanation.

It will be understood that when an element such as a layer, film, region, or substrate is referred to as being “on” another element, it may be directly on the other element or intervening elements may also be present. In contrast, when an element is referred to as being “directly on” another element, there are no intervening elements present. The word “on” or “above” means disposed on or below the object portion, and does not necessarily mean disposed on the upper side of the object portion based on a gravitational direction.

Unless explicitly described to the contrary, the word “comprise”, and variations such as “comprises” or “comprising”, will be understood to imply the inclusion of stated elements but not the exclusion of any other elements.

The phrase “in a plan view” means viewing an object portion from the top, and the phrase “in a cross-sectional view” means viewing a cross-section of which the object portion is vertically cut from the side.

The terms “-er”, “-or”, and “module” described in the specification mean units for processing at least one function and operation, and can be implemented by hardware components or software components, and combinations thereof. In addition, “ . . . modules”, “ . . . units”, or “ . . . modules” may be integrated into at least one module and implemented with at least one processor, except for “ . . . portion”, “ . . . unit”, or “ . . . module” that needs to be implemented with specific hardware.

In this specification, “transmission” or “provision” may include not only transmitting or providing directly, but also indirectly transmitting or providing through another device or using a bypass path.

Expressions written as singular in this specification may be interpreted as singular or plural, unless explicit expressions such as “one” or “single” are used.

Hereinafter, several embodiments of the present disclosure will be described in detail so that those skilled in the art to which the present disclosure pertains may easily practice the present disclosure. However, the present disclosure may be implemented in various different forms and is not limited to embodiments provided herein.

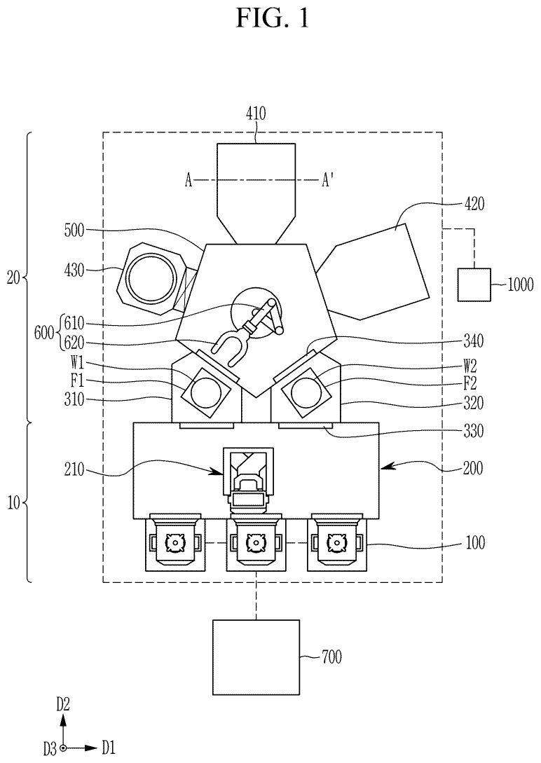

FIG. 1 shows a schematic view on a substrate processing system according to an embodiment of the present disclosure.

Referring to FIG. 1, the substrate processing system may include an equipment front end module 10 and a process module 20. The equipment front end module 10 may be arranged on one side of the process module 20. For example, the equipment front end module 10 may be arranged on the front end of the process module 20.

The equipment front end module 10 may include load ports 100 and an index module 200. The process module 20 may include a first load-lock chamber 310, a second load-lock chamber 320, a first process chamber 410, a second process chamber 420, an arrange chamber 430, a transfer chamber 500, and a transfer robot 600.

The index module 200 may be arranged between the load ports 100 and the process module 20. The index module 200 transfers wafers W1 and W2 between the load ports 100 and the process module 20. The respective load ports 100 provide a space in which a front opening unified pod (FOUP) into which the wafers W1 and W2 are received is placed. The index module 200 may include an index robot 210. The index robot 210 may take the wafers W1 and W2 before undergoing a process from the FOUP disposed on the load port 100 and may transfer the same to the process module 20. The index robot 210 may take the wafers W1 and W2 processed by the process module 20 to the FOUP.

The process module 20 may include a first load-lock chamber 310, a second load-lock chamber 320, an arrange chamber 430, a first process chamber 410, a second process chamber 420, and a transfer chamber 500. The transfer chamber 500 may have a polygonal shape in a plan view. The first and second load-lock chambers 310 and 320, the arrange chamber 430, and the first and second process chambers 410 and 420 may be arranged on respective sides of the transfer chamber 500. The first and second load-lock chambers 310 and 320 may be arranged on the sides of the transfer chamber 500 that are the nearest to the equipment front end module 10.

For example, the transfer chamber 500 may have a pentagonal shape in a plan view. The transfer chamber 500 may have five sides. Two process chambers 410 and 420, two load-lock chambers 310 and 320, and one arrange chamber 430 may be arranged on each side. However, a technical scope of the present disclosure is not limited to this. The shape of the transfer chamber 500, and the types and the number of the chambers disposed near the transfer chamber 500 may be modifiable depending on the processes or conditions.

In an embodiment, the first load-lock chamber 310 may include a space in which a first FOUP F1 storing first wafers W1 is provided. The first load-lock chamber 310 may provide a space for temporarily storing the first wafers W1 taken out of/in the process module 20. An inner portion of the first load-lock chamber 310 may be switched between vacuum and atmospheric pressure. Hence, inner portions of the transfer chamber 500, the arrange chamber 430, the first process chamber 410, and the second process chamber 420 may be maintained at vacuum, and an inner portion of the equipment front end module 10 may be maintained at the atmospheric pressure.

In an embodiment, the second load-lock chamber 320 may include a space in which a second FOUP F2 storing the second wafers W2 is provided. The second load-lock chamber 320 may provide a space for temporarily storing the second wafers W2 taken in/out of the process module 20. An inner portion of the second load-lock chamber 320 may be switched to the vacuum or the atmospheric pressure. Hence, inner portions of the transfer chamber 500, the arrange chamber 430, the first process chamber 410, and the second process chamber 420 may be maintained at vacuum, and the inner portion of the equipment front end module 10 may be maintained at the atmospheric pressure.

A first gate valve 330 may be installed between the respective first and second load-lock chambers 310 and 320 and the equipment front end module 10. A second gate valve 340 may be installed between the respective first and second load-lock chambers 310 and 320 and the transfer chamber 500. One of the first gate valve 330 and the second gate valve 340 may be opened so that the inner portions of the transfer chamber 500, the arrange chamber 430, the first process chamber 410, and the second process chamber 420 may maintain the vacuum.

The transfer robot 600 may be arranged inside the transfer chamber 500. The transfer robot 600 may transfer the first wafers W1 between the first load-lock chamber 310 and the arrange chamber 430 or between the first load-lock chamber 310 and the first and second process chambers 410 and 420. In another embodiment, the transfer robot 600 may transfer the second wafers W2 between the second load-lock chamber 320 and the arrange chamber 430 or between the second load-lock chamber 320 and the first and second process chambers 410 and 420.

The transfer robot 600 may include a robot arm 610 and a robot hand 620. The robot hand 620 may grab the first wafers W1 and/or the second wafers W2. The robot arm 610 may move in directions D1, D2, and D3.

The arrange chamber 430 may arrange the wafers W1 and W2 so that the respective wafers W1 and W2 may be arranged in a same direction before the wafers W1 and W2 are loaded in the process chambers 410 and 420.

The respective first and second process chambers 410 and 420 may perform a process for processing the first and second wafers W1 and W2. In detail, a semiconductor process may be performed on the first and second wafers W1 and W2 in the first and second process chambers 410 and 420. The first and second process chambers 410 and 420 may include a processing space inside thereof.

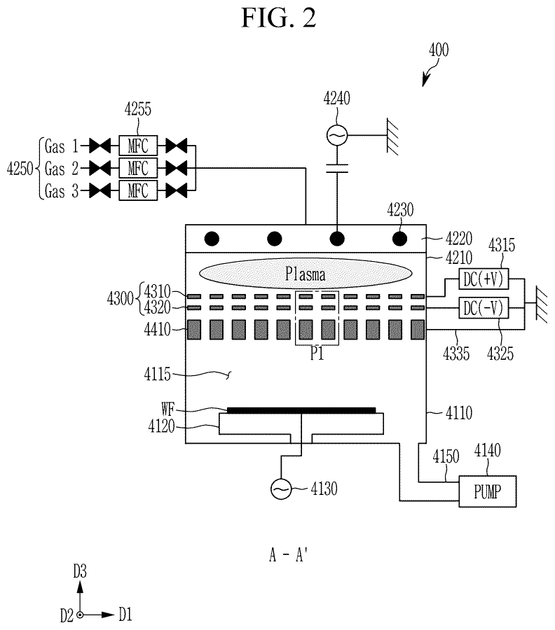

The first and second process chambers 410 and 420 may include at least one substrate processing device 400 of FIG. 2 by which a semiconductor process is performed inside thereof. At least one substrate processing device 400 may be included. The semiconductor process may include at least one of an etching process, a developing process, and a deposition process. For example, the semiconductor process may include a dry developing process.

In an embodiment, the substrate processing system may further include a third process chamber 700. The third process chamber 700 may include a processing space in which another semiconductor process is further performed before/after a semiconductor process is performed in the first and second process chambers 410 and 420. For example, the third process chamber 700 may allow the wafer to which photoresist is deposited to undergo a process such as exposure. The wafer to which photoresist is deposited in the third process chamber 700 may be provided on the load port 100, it may be input to the first and second process chambers 410 and 420 according to the above-noted process, and a developing process may be performed.

The control module 1000 may control the first and second load-lock chambers 310 and 320, the arrange chamber 430, the first and second process chambers 410 and 420, the transfer chamber 500, and the transfer robot 600. The control module 1000 may control cleaning the first and second process chambers 410 and 420. The control module 1000 may check the number of wafers disposed in the first and second load-lock chambers 310 and 320.

In an embodiment, when the semiconductor process is performed in the first and second process chambers 410 and 420, by-products may be piled in the first and second process chambers 410 and 420. When the by-products are piled in the first and second process chambers 410 and 420, this may give an influence on the semiconductor process to be formed. Therefore, the by-products piled in the first and second process chambers 410 and 420 are to be removed by periodically cleaning the first and second process chambers 410 and 420. The control module 1000 may control the time for cleaning the first and second process chambers 410 and 420. This is a non-limited example, and the control module 1000 may control a general operation of the substrate processing system, and may be connected to the third process chamber 700 to control the previous process or subsequent processes.

FIG. 2 shows a cross-sectional view on a substrate processing device 400 with respect to a line A-A′ of FIG. 1 according to an embodiment of the present disclosure.

Referring to FIG. 2, in an embodiment, the substrate processing device 400 may include a process chamber 4110, a plasma chamber 4210, a power voltage source 4240, a grid structure 4300, and a reflector 4410. The substrate processing device 400 may perform a dry developing process using plasma on the substrate WF during the semiconductor process. However, the scope of the present invention is not limited thereto. According to the embodiment, it may include the case in which the deposition process, the etching process, and the cleaning process are performed together in the substrate processing device 400. FIG. 2 shows that the first process chamber 410 includes a single substrate processing device 400, which is a non-limited example, and the case in which multiple substrate processing devices 400 are included in the first process chamber 410 may be included.

The substrate WF may represent the semiconductor substrate, or the stacking structure including a substrate and predetermined layers or films formed on a surface thereof. The surface of the substrate WF may represent an exposed surface of the substrate, or expose surfaces such as predetermined layers or films formed on the substrate.

For example, the substrate WF may be a wafer or may include a wafer and at least one material film on the wafer. The material film may be an insulation layer and/or a conductive layer formed on the wafer by various methods such as deposition or coating plating. The insulation layer may include a film such as an oxide layer, a nitride layer, or an oxynitride layer. The conductive layer may include a film such as a metal layer or a polysilicon layer.

In an embodiment, the material film may be a single film or a multilayer. When the material film is a multilayer, it may be a film in which the insulation layer or the conductive layer is arranged as multiple layers, and may be a film in which the insulation layer and the conductive layer are alternately arranged. The material film may have a predetermined pattern and may be formed on the wafer.

The process chamber 4110 may define a processing region 4115 for processing the substrate. In detail, the process chamber 4110 may define a lower surface of the reflector 4410 as a processing region 4115 for processing the substrate. The processing region 4115 may represent a region in which the substrate WF is processed, in which the semiconductor process such as a dry developing process is directly performed on the substrate WF. The processing region 4115 may represent a space sealed from an outside, and a semiconductor process may be performed on the substrate WF in the space.

In an embodiment, the process chamber 4110 may have an entire exterior structure in a shape such as a circular cylindrical shape, an oval columnal shape, or a polygonal shape. The process chamber 4110 may be made of a metallic material. The process chamber 4110 may maintain an electrical ground state to block noise from the outside when processing the substrate.

In an embodiment, a liner may be provided to the inside of the process chamber 4110. The liner may protect the process chamber 4110, and may cover the metal structures in the process chamber 4110 to prevent generation of metal contamination caused by arcing from the inside.

In an embodiment, the liner may be made of a metallic material such as aluminum or a ceramic material. In detail, the liner may be made of a material film that resists to plasma. The material film that resists to plasma is a non-limited example, and may include an yttrium oxide (Y₂O₃) film.

The process chamber 4110 may be connected to a pumping system 4140 through a discharge pipe 4150. The by-products after the substrate processing may be discharged through the discharge pipe 4150 using the pumping system 4140. The by-products may be a material remaining inside the process chamber 4110 after the substrate processing, in detail, the substrate developing process for forming a pattern on the substrate. The remaining material may be a residue such as neutrons to be described.

In an embodiment, the pumping system 4140 may adjust pressure inside the process chamber 4110. In detail, the pumping system 4140 may include a turbo molecule vacuum pump (TMP) with pumping rates reaching 5000 seconds (or more). The turbo molecule vacuum pump may be generally used in processing low pressures of less than 50 mTorr.

In another embodiment, the pumping system 4140 may process high pressures (i.e., greater than 100 mTorr). The pumping system 4140 for pressing high pressures is a non-limited example, and a pump such as a mechanical booster pump or a dry roughing pump may be used.

In an embodiment, the process chamber 4110 may include a pressure measuring device for monitoring pressure inside the chamber. In detail, the pressure measuring device may measure the pressure inside the process chamber 4110. In further detail, the pressure measuring device may measure the pressure inside the process chamber 4110 to adjust the pumping rates of the pumping system 4140. The rates of the by-products (e.g., neutral beams) discharged through the discharge pipe 4150 may be adjusted by measuring the pressure inside the process chamber 4110.

In an embodiment, a substrate supporting unit 4120 may be installed inside the process chamber 4110. The substrate supporting unit 4120 may be arranged on a lower portion of the processing region 4115 in the process chamber 4110. The substrate supporting unit 4120 may support the substrate WF.

The substrate supporting unit 4120 may include an electrostatic chuck for supporting the substrate WF with an electro-static force, and a chuck support for supporting the electrostatic chuck.

The electrostatic chuck may include an electrode for chucking and de-chucking the substrate WF inside the same. The chuck support may support the electrostatic chuck arranged on the upper portion, and may be made of metal such as aluminum or a ceramic insulator such as alumina. In detail, a power supplying wire connected to the electrode of the electrostatic chuck may be arranged on the chuck support. This is a non-limited example, the substrate supporting unit 4120 may be configured to support a vacuum chuck for supporting the substrate WF using vacuum or mechanically support the substrate WF in addition to an electrostatic chuck.

The substrate supporting unit 4120 may further include a lift pin. The lift pin may be configured to lift the substrate WF from the surface of the substrate supporting unit 4120 on which the substrate WF is disposed. The lift pin may be received in a hole provided in the substrate supporting unit 4120. In detail, the lift pin may be installed to be moveable in the vertical direction on the substrate supporting unit 4120. The lift pin may move in the vertical direction and may ascend and descend the substrate WF. The substrate supporting unit 4120 may include the number of lift pins, which are appropriate in supporting the substrate WF. This is a non-limited example, and the substrate supporting unit 4120 may include at least three lift pins that are equally spaced apart from each other in a circumferential direction of the substrate supporting unit 4120, but is not limited thereto.

When the substrate WF that is a processing target is taken into the inside of the process chamber 4110 or is taken out of the process chamber 4110, the lift pin may become a pin-up state protruding upward from the substrate supporting unit 4120 and may support the substrate WF. While the substrate WF is processed in the process chamber 4110, the lift pin may become a pin-down state in which the same is descended below the upper surface of the substrate supporting unit 4120 and the substrate WF may be disposed on the substrate supporting unit 4120.

In an embodiment, an RF bias source 4130 may be connected to the substrate supporting unit 4120. The RF bias source 4130 may supply RF power voltage to the substrate supporting unit 4120. For example, the RF bias source 4130 may supply RF power voltage with a low frequency that is less than about 200 kHz to the substrate supporting unit 4120 while progressing a developing process on the substrate WF. In another embodiment, the RF bias source 4130 may remove the RF power voltage supplied to the substrate supporting unit 4120 while progressing a developing process on the substrate WF.

The plasma chamber 4210 may be arranged in the process chamber 4110. The plasma chamber 4210 may define a plasma generating region Plasma. The plasma generating region may generate plasma and/or radical by the power voltage source 4240 installed outside the plasma chamber 4210 and may supply the plasma and/or the radical to the plasma generating region.

In an embodiment, the plasma chamber 4210 may include a lid 4220, a coil 4230, a showerhead, and a power voltage source 4240 disposed in the plasma chamber 4210. The plasma chamber 4210 may, for example, generate plasma through an inductively coupled plasma (ICP) coil and may perform a semiconductor process.

The lid 4220 may be disposed in the plasma chamber 4210. The lid 4220 may cover an upper end of the plasma chamber 4210, and may seal the chamber and may maintain a process environment inside the same. In detail, the lid 4220 may be arranged in the plasma chamber 4210, surrounding members such as the coil 4230 and the showerhead.

In an embodiment, the lid 4220 may seal the plasma chamber 4210 and may maintain the process environment of the inside thereof. In further detail, the lid 4220 may control a gas flow, pressure, and temperature inside the chamber, and may further include a gas inlet or a measurement device.

In an embodiment, the lid 4220 may be made of a metallic material. In detail, the metallic material may, for example, include a metallic material such as aluminum (Al). The lid 4220 may be made of a metallic material, and may maintain the electrical ground state to block noise from the outside during the plasma process.

In an embodiment, a liner may be provided inside the lid 4220. The liner may protect the lid 4220, and may cover the metal structures inside the lid 4220 to prevent generation of metal contamination caused by arcing of the inside. The liner is a non-limited example, and may be a metallic material such as aluminum, or a ceramic material.

The liner may be made of a material film that is resistant to plasma. The material film that is resistant to plasma may, for example, be an yttrium oxide (Y₂O₃) film. The material film that is resistant to plasma is not limited to the yttrium oxide film.

The showerhead may be arranged in the plasma chamber 4210. The showerhead may be a member including holes in which gas is moveable. In detail, the showerhead may allow the gas supplied from the outside of the plasma chamber 4210 to be uniformly distributed to the plasma generating region through the holes of the showerhead.

In an embodiment, the plasma chamber 4210 may receive gas from a gas supply portion 4250. The gas supply portion 4250 may be arranged outside the plasma chamber 4210 and may supply gas to the plasma chamber 4210 through the showerhead.

The gas may, for example, be silicon, oxygen, carbon gas, inert gas, halogen gas, or any combination thereof. The gas may supply at least one of the above-noted gas to the plasma chamber 4210. In detail, the gas may include the inert gas as main gas, and the inert gas may be hydrogen (H₂), nitrogen (N₂), helium (He), argon (Ar), or any combination thereof.

The inert gas does not react to ceramic and metal that is a material of the plasma chamber 4210 and does not corrode the chamber or generate particles. The conventional dry developing process may perform a process using halogen gas such as chlorine (Cl), bromine (Br), or fluorine (F) to generate R—Sn—X (X=halogen element) that is a volatility material as a reaction product and contaminate the FOUP or the line of the subsequent movement process, which is a problem. On the contrary, the substrate processing device 400 according to the present disclosure may solve the problem of the above-described conventional art by using the inert gas.

The power voltage source 4240 may be installed outside the plasma chamber 4210. The power voltage source 4240 may generate plasma and/or radical and may supply the plasma and/or the radical to the plasma generating region.

For example, the power voltage source 4240 may supply the plasma and/or the radical to the plasma generating region 215 through the plasma supply line 245. The plasma and/or the radical may pass through the showerhead and may be supplied to the plasma generating region.

The power voltage source 4240 may supply power to generate the plasma and/or the radical. The power may, for example, be supplied as radio frequency (RF) power in an electromagnetic wave form with a predetermined frequency and intensity. The power may have an electromagnetic wave form, may have an on-off period, and may be supplied in a continuous wave form or a pulse form.

In an embodiment, the plasma may include various types of components such as radical, ion, electron, and ultraviolet rays. At least one of the components such as the radical, ion, electron, or ultraviolet rays may be used in processing the substrate WF.

In an embodiment, the plasma chamber 4210 may further include an adaptor. The adaptor may be arranged between the power voltage source 4240 and the showerhead 4230. The adaptor may be a moving passage of the plasma and/or radical supplied from the power voltage source 4240. The plasma and/or the radical generated by the power voltage source 4240 may pass through the adaptor and may be provided to the showerhead 4230.

The grid structure 4300 may be arranged between the process chamber 4110 and the plasma chamber 4210. The grid structure 4300 may provide ion and/or radical disposed inside the plasma chamber 4210 to the reflector 4410. For example, the ion may be provided to the reflector 4410 by supplying a voltage to the grid structure 4300.

The ion may be supplied to the reflector 4410 by a potential difference of the voltage supplied to the grid structure 4300. The ion has charges, and it may have directivity and may be supplied to the reflector 4410.

The grid structure 4300 may include a first grid 4310 and a second grid 4320 arranged below the first grid 4310. In detail, the first grid 4310 may be arranged near the plasma chamber 4210, and the second grid 4310 may be arranged below the first grid 4310.

The first grid 4310 may be arranged farther from the substrate WF than the second grid 4320. In detail, a distance in the vertical direction from the upper surface of the substrate WF to the first grid 4310 may be greater than a distance in the vertical direction from the upper surface of the substrate WF to the second grid 4320.

A bias may be applied to the first and second grids 4310 and 4320. In detail, when the bias is applied to the first and second grids 4310 and 4320, ions may be extracted from the plasma of the plasma chamber 4210 to form ion beams. In further detail, when the bias is applied to the first and second grids 4310 and 4320, the ion beams may be provided to the reflector 4410.

In an embodiment, the first and second grids 4310 and 4320 may include holes. In detail, the ions may pass through the holes and may be provided to the reflector 4410.

In an embodiment, the first grid 4310 may be connected to a first power source 4315. The first power source 4315 may apply a bias to the first grid 4310. For example, the first power source 4315 may apply a positive voltage to the first grid 4310.

In an embodiment, the second grid 4320 may be connected to the second power source 4325. The second power source 4325 may apply a bias to the second grid 4320. For example, the second power source 4325 may apply a negative voltage to the second grid 4320.

In an embodiment, a voltage that is higher than that applied to the second grid 4320 may be applied to the first grid 4310. For example, the voltage applied to the first grid 4310 may be 100 to 1000 V, and the voltage applied to the second grid 4320 may be −1000 to −100 V.

In an embodiment, the voltage applied to the first grid 4310 and the voltage applied to the second grid 4320 may satisfy Condition 1.

$$\vert {G}_{1} - {G}_{2} \vert \geq 600 V \qquad 〈 Condition 1 〉$$

Here, G₁ and G₂ represent the voltage supplied to the first grid and the voltage supplied to the second grid, and |G₁-G₂| represents an absolute value of a difference value of G₁ and G₂.

Condition 1 may represent an index on a divergence angle of the ion beams passing through the grid structure 4300 when a developing process is performed on the substrate WF. Condition 1 indicates the absolute value on the difference value between the voltage supplied to the first grid 4310 and the voltage supplied to the second grid 4320, and it may be equal to or greater than 600 V, for instance, 600 V to 800 V.

When Condition 1 is satisfied, the etch amount of photoresist to be removed with energy of neutrons may be easily controlled. When Condition 1 is not satisfied, efficiency of the etch amount of photoresist may be deteriorated.

In an embodiment, the absolute value of the voltage applied to the first grid 4310 may be greater than the absolute value of the voltage applied to the second grid 4320. The absolute value of the voltage applied to the first grid 4310 determines the energy of ions, and when the difference value with the voltage applied to the second grid 4320 increases, the ions are accelerated further intensely in the direction to the second grid 4320 from the first grid 4310, collision energy of the ions accelerated by the reflector 4410 increases so the neutral beams may be easily generated, which is a merit.

Hence, a sign of the voltage applied to the first grid 4310 may be different from a sign of the voltage applied to the second grid 4320. Differing from FIG. 2, for example, a negative voltage may be supplied to the first grid 4310, and a positive voltage may be supplied to the second grid 4320.

The reflector 4410 may allow the ions passing through the holes of the first and second grids 4310 and 4320 to collide with each other to form neutral beams. The neutral beams represent beams configured with a set of electrically neutral particles. In detail, the reflector 4410 may form the neutral beams by neutralizing the ions.

In an embodiment, the reflector 4410 may be connected to a ground voltage. The ions accelerated by the first and second grids 4310 and 4320 may collide with the reflector 4410 grounded by the ground voltage and may generate neutral beams including neutrons partly losing energy. The neutral beam may reach the substrate WF and a dry developing process may be performed.

In an embodiment, the reflector 4410 may include holes, and the ions may collide with each other in the holes. The reflector 4410 may form the neutral beams by the collision of ions. In detail, the ions input to the first and second grids 4310 and 4320 from the plasma collide with the reflector 4410, during which the neutral beams including neutrons are formed from the ions. The neutral beams having passed through the reflector 4410 may reach the substrate WF, and a dry developing process for forming patterns on the substrate may be performed.

The substrate processing device 400 uses the neutral beams by the reflector 4410 for processing the substrate, thereby including the merit of the dry development by which the line pattern is not broken and no bridge is formed. Further, during the exposure, EUV non-exposed portion with substantially low density may be selectively removed by physical sputtering, by using a phenomenon in which density increases according to a crosslinking reaction of resist containing metal. The neutral beams do not generate charges but are vertical, thereby allowing an anisotropic phenomenon and preventing line patterns from being damaged.

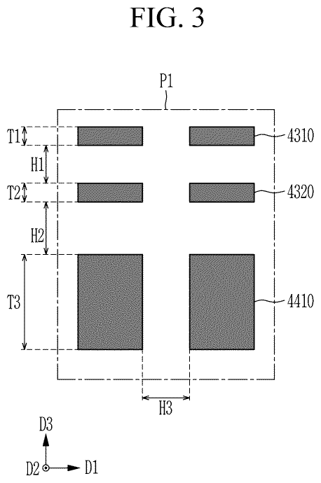

FIG. 3 shows an enlarged view on a region P1 of FIG. 2.

Referring to FIG. 3, in an embodiment, a ratio (first gap:second gap) of a first gap H1 between the first grid 4310 and the second grid 4320 to a second gap H2 between the second grid 4320 and the reflector 4410 may be 1:1 to 1:5. In detail, the ratio of the gaps may be 1:1.5 to 1:3.

As the first gap H1 and the second gap H2 are arranged in the above-noted gap range, the ionization process of plasma by the first and second grids 4310 and 4320 and the ion neutralization process by the reflector 4410 may be easily performed. When the ratio of the gaps deviates from the above-noted range, the ions with charges do not collide with each other in the holes in the reflector 4410 but leave for the outside so there is a problem in processing the substrate WF.

In an embodiment, a thickness T1 of the first grid 4310 and a thickness T2 of the second grid 4320 may be less than a thickness T3 of the reflector 4410. In detail, the thickness T3 of the reflector 4410 in a direction D3 that is a vertical direction may be greater than the thickness T1 of the first grid 4310 and the thickness T2 of the second grid 4320.

The thicknesses of the first and second grids 4310 and 4320 are formed to be less than the thickness T3 of the reflector 4410, and the ions collide to each other many times in the holes in the reflector 4410, thereby easily controlling formation of the neutral beams. FIG. 3 shows that the thicknesses T1 and T2 of the first and second grids 4310 and 4320 are the same, which is a non-limited example, and the thicknesses T1 and T2 of the first and second grids 4310 and 4320 may be different from each other.

In an embodiment, the ratio (T3/H3) of the thickness T3 of the reflector 4410 to the gap H3 between the holes of the reflector 4410 may be 3 to 15. In detail, the ratio may be 5 to 10, and in further detail, the ratio may be 4 to 8.

As the ratio satisfies the above-noted range, the ions accelerated by the first and second grids 4310 and 4320 may easily collide to each other to generate neutrons. When the ratio fails to satisfy the above-noted range, the accelerated ions may not easily collide with interior walls of the holes of the reflector 4410 and may not generate a large amount of neutrons.

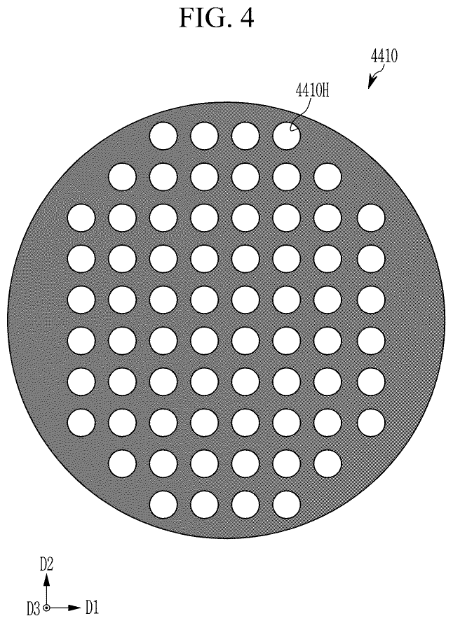

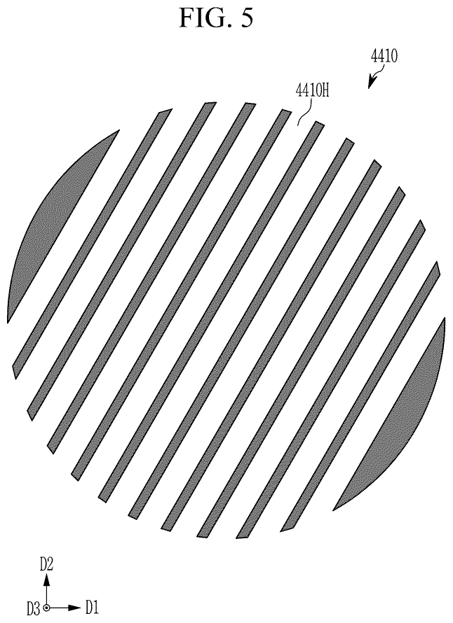

FIG. 4 and FIG. 5 show top plan views of a reflector 4410 according to an embodiment of the present disclosure.

Referring to FIG. 4 and FIG. 5, the reflector 4410 may include at least one of a slit type and a hole type. As the reflector 4410 includes at least one of the slit type and the hole type having holes 4410H, the ions having passed through the first and second grids 4310 and 4320 are provided to the holes 4410H, and the interior walls of the holes 4410H collide with the ions to form neutrons from the ions.

Referring to FIG. 4, the reflector 4410 shows the slit type and includes the holes 4410H. FIG. 4 shows that the holes 4410H are continuously formed, which is a non-limited example, and may include discontinuously formed holes.

Referring to FIG. 5, the reflector 4410 shows the hole type and includes the holes 4410H. FIG. 5 shows that the holes 4410H are continuously formed, which is a non-limited example, and may include discontinuously formed holes.

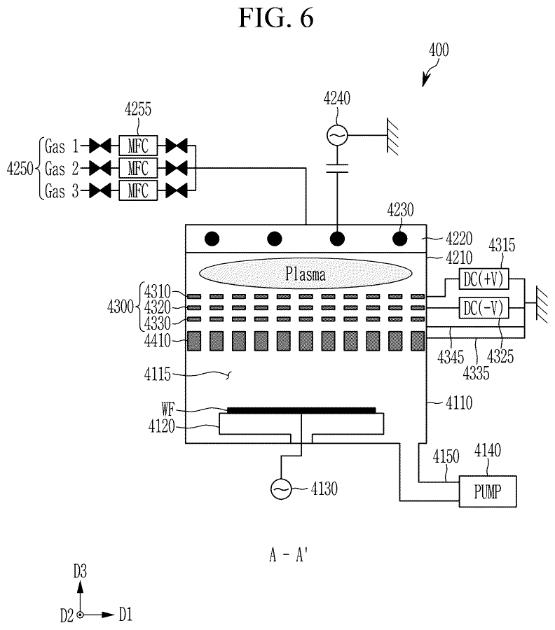

FIG. 6 to FIG. 8 show cross-sectional views on a substrate processing device 400 according to another embodiment of the present disclosure.

Referring to FIG. 6, in an embodiment, the grid structure 4300 of the substrate processing device 400 may include at least one third grid 4330. The third grid 4330 may be disposed below the second grid 4320. A shape of the third grid 4430 may correspond to the first and second grids 4310 and 4320 within an allowable range.

A third voltage 4345 may be applied to the third grid 4330. In detail, the third voltage 4345 may be a ground voltage. The third grid 4330 may be grounded by the ground voltage and may undergo a pre-process for forming neutral beams by the reflector 4410. In detail, the ions accelerated by the first and second grids 4310 and 4320 may pass through the third grid 4330 and some of the ions may lose energy. Some ions starting to lose energy may easily collide with the holes in the reflector 4410 and may easily form the neutral beams.

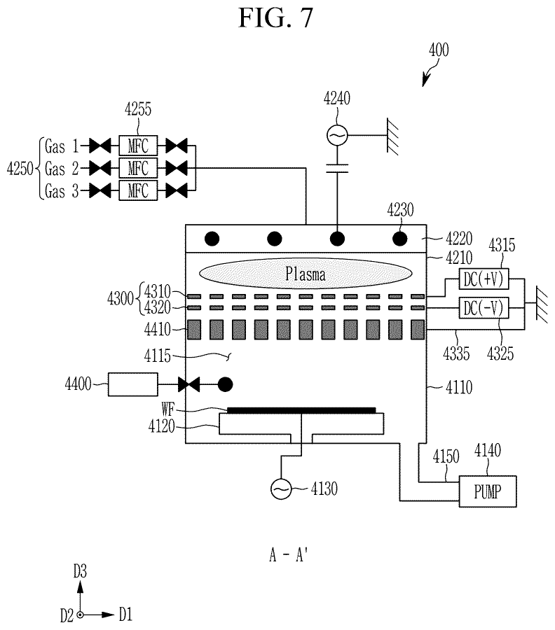

Referring to FIG. 7, in an embodiment, the substrate processing device 400 may include a residual gas analyzer 4400. The residual gas analyzer 4400 may analyze the gas remaining in the process chamber 4110 and may determine an appropriate state of the process. In detail, the residual gas analyzer 4400 may detect a component or concentration of the residual gas and may determine whether the process is appropriately performed according to predetermined values.

In an embodiment, the residual gas analyzer 4400 may be arranged near the outside wall of the process chamber 4110. The residual gas analyzer 4400 may detect the residual gas in the process chamber 4110 by a direct connection method or an indirect monitoring method. By the direct connection method, the residual gas analyzer 4400 may be directly connected to the process chamber 4110 using a pipe or a tube, and may directly extract the gas remaining in the process chamber 4110 and may analyze the extracted gas.

The indirect monitoring method may include including a transmitting member, such as a window, on the side wall of the process chamber 4410, and allowing the residual gas analyzer 4400 to indirectly determine the gas state through the window.

In an embodiment, the residual gas analyzer 4400 is a gas analysis device, and may, for example, include a residual gas analyzer (RGA), a quadrupole mass spectrometer (QMS), a Fourier transform infrared (FTIR) spectrometer, a gas chromatography (GC) device, an optical emission spectrometer (OES), and a process mass spectrometer. This is a non-limited example, and various gas analysis devices for directly or indirectly monitoring the gas in the process chamber 4110 may be used.

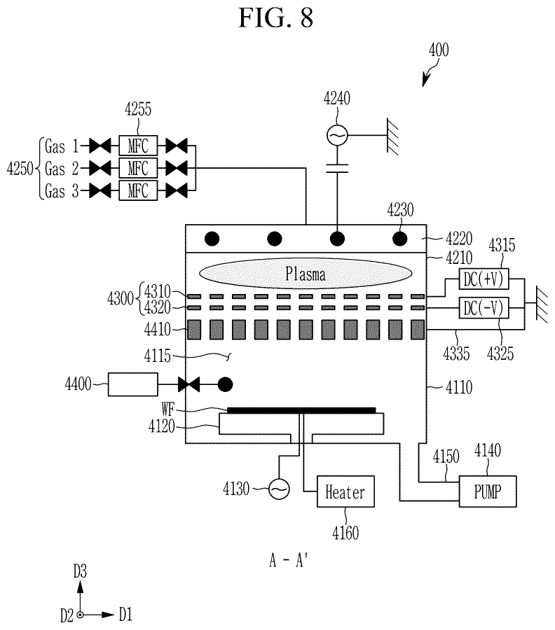

Referring to FIG. 8, in an embodiment, the substrate supporting unit 4120 may include a heating member 4160. In detail, the heating member 4160 may be a member such as a heater and may supply heat to the substrate supporting unit 4120. The heating member 4160 may supply heat to the substrate supporting unit 4120 to increase a temperature of the substrate WF disposed on the substrate supporting unit 4120.

In an embodiment, the heating member 4160 may control the temperature of the substrate WF within a range of 10 to 150° C. In detail, the temperature may be 10 to 80° C., in detail, 10 to 40° C. By controlling the substrate WF to be at the above-noted temperature, the time of the developing process may be reduced, and resolution of photoresist may be increased, thereby further easily forming the pattern.

As described above, as the substrate supporting unit 4120 further includes the heating member 4160, a baking process for preprocessing the substrate WF before/after the developing process may be additionally performed, thereby increasing process efficiency.

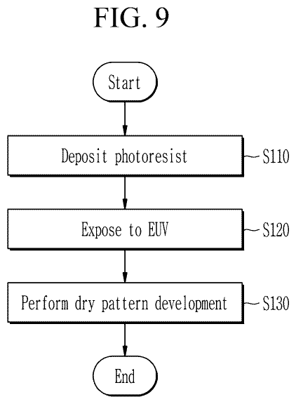

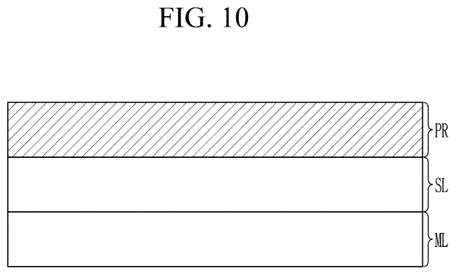

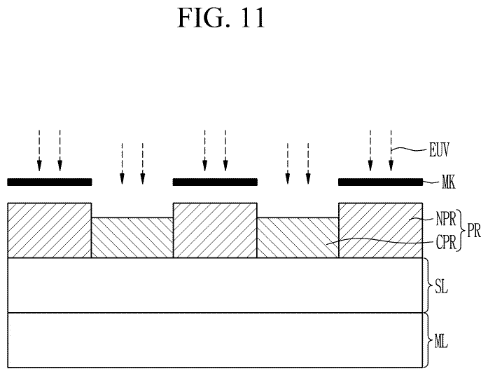

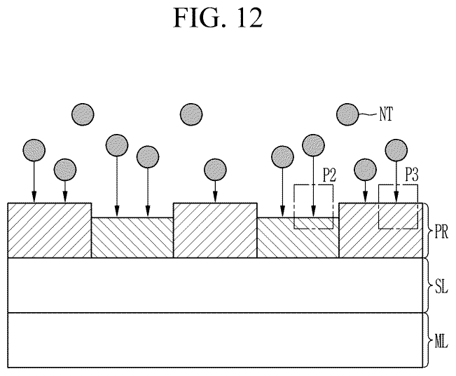

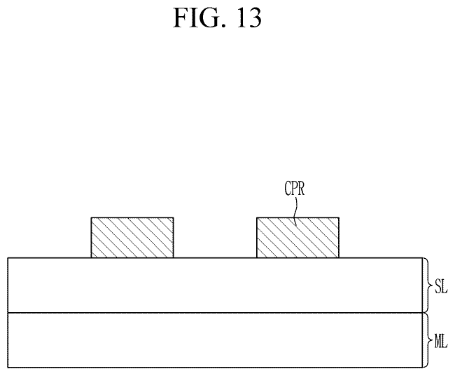

FIG. 9 shows a flowchart illustrating a substrate processing method using a substrate processing device according to the present disclosure, and FIG. 10 to FIG. 13 show the substrate processing method.

Referring to FIG. 9, the substrate processing method includes depositing photoresist (PR) on a substrate WF (S110), exposing the photoresist with extreme ultraviolet rays (EUV) to thus perform an exposure (S120), and a dry pattern developing (S130). FIG. 10 corresponds to deposition of photoresist on the substrate S110, FIG. 11 corresponds to the exposure S120, and FIG. 12 to FIG. 13 correspond to the dry pattern developing S130. FIG. 10 to FIG. 13 show that the substrate WF includes a main layer ML and a sub-layer SL disposed on the main layer ML, and the substrate WF may include no main layer ML.

Referring to FIG. 9 and FIG. 10, deposition of photoresist on the substrate S110 may include depositing photoresist PR on the sub-layer SL. In detail, the depositing photoresist PR on the sub-layer SL may be preparing a basis for forming a precise pattern on the substrate.

In an embodiment, the photoresist PR may be deposited on the substrate by a wet or dry method. The wet method may include applying liquefied photoresist PR to uniformly coat the photoresist PR on the sub-layer SL. The wet method may include, for example, performing a spin coating or an immersing coating.

The dry method may include transforming the photoresist PR into a gas state and depositing the same on the sub-layer SL. The dry method may, for example, include the chemical vapor deposition (CVD) for forming a solid by depositing gas of the photoresist PR generated by a chemical reaction on a surface of the sub-layer SL; and the physical vapor deposition (PVD) for gasifying the photoresist PR by a physical method and depositing the same on the surface of the sub-layer SL.

In an embodiment, the photoresist PR may include metal with excellent rate of absorbing extreme ultraviolet rays (EUV). The photoresist PR may be, as a non-limited example, made of an organic metal oxide or an organic metal containing material including metal with an excellent rate of absorbing the extreme ultraviolet rays, such as tin (Sn), hafnium (Hf), bismuth (Bi), zirconium (Zr), zinc (Zn), antimony (Sb), platinum (Pt), or indium (In).

Referring to FIG. 9 and FIG. 11, the exposure S120 for exposing photoresist PR to the extreme ultraviolet rays (EUV) includes exposing the above-noted photoresist PR containing metal to EUV radiant rays. The EUV may induce changes in the chemical compositions and cross-linking of metal-containing photoresist films, creating contrast in etching selectivity that may be used for the subsequent developing process.

In detail, the exposure S120 may control whether the photoresist PR is condensed between regions using a mask MK. The condensation may be controlled by the EUV irradiation. In detail, some regions of the photoresist PR directly irradiated by the EUV are transformed into condensed photoresist (CPR). In contrast, the photoresist PR disposed below the mask MK and not directly irradiated by the EUV may be classified as non-condensed photoresist (NPR). In this way, the exposure S120 may include forming a fine pattern in advance before the developing process by condensing the photoresist PR.

Referring to FIG. 9, FIG. 12, and FIG. 13, the dry pattern developing S130 may be performed in the substrate processing device 400 of the present disclosure, and may include removing unnecessary parts of the photoresist PR on the substrate having undergone the exposure and finally forming the pattern. In detail, the substrate processing device 400 may form neutral beams and may provide the neutral beams to the substrate to form a pattern, and a detailed description thereof may be referenced within a range that does not contradict the above-described content.

In an embodiment, the dry pattern developing S130 may include providing a substrate WF that has undergone exposure to the substrate processing device 400, flowing a gas into the substrate processing device 400 to ignite plasma, and forming neutral beams from the plasma and irradiating the same to the substrate WF.

The providing of the substrate WF having undergone the exposure to the substrate processing device 400 may include placing the substrate WF in the substrate supporting unit 4120 in the substrate processing device 400 to perform a developing for forming a detailed pattern on the substrate on which a fine pattern is formed. For detailed description of this, please refer to the above content.

The igniting of plasma by flowing gas into the substrate processing device 400 may ignite plasma in the plasma chamber 4210 by flowing gas from the gas supply portion 4250 in the substrate processing device 400. The gas may be, as a non-limiting example, silicon, oxygen, carbon gas, inert gas, halogen gas or any combination thereof, and may include inert gas as the main gas. In this way, by using the inert gas in the process, the risk of corroding the chamber and the possibility of generating particles may be minimized by not reacting to the chamber material.

In an embodiment, a flux of the gas may be 10 to 80 sccm. The flux may be 10 to 50 sccm. By controlling the flux of the gas within the above-mentioned range, plasma ignition may be easily performed.

In an embodiment, the process pressure when igniting the plasma may be 0.2 to 1.0 mTorr. In detail, the pressure of the process may be 0.3 to 0.8 mTorr.

The forming of neutral beams from the plasma and irradiating the same on the substrate WF may include allowing ions from the plasma to pass through the grid structure 4300, and neutralizing the ions passing through the grid structure 4300.

The allowing of ions from the plasma to pass through the grid structure 4300 may include accelerating the ions from the plasma to pass through the grid structure 4300, in detail, to pass through the first grid 4310 and the second grid 4320.

The neutralizing of the ions having passed through the grid structure 4300 may include allowing the accelerated ions to collide with the reflector 4410, and allowing the ions to lose some of their energy. In this process, the ions may form neutrons (NT), and the neutrons may gather together in multiples to form neutral beams, and the neutral beams may be provided to the substrate to form a pattern of the photoresist.

As described, by using the inert gas to form the neutral beams containing neutrons (NT) and using the same in the developing process, the FOUP and the line in the subsequent process may not be contaminated, and the inner portion of the device may not be contaminated. In addition, when developing the pattern using neutral beams with strong linearity and no charges, the substrate may be patterned to have anisotropy, making it easy to remove areas that are not exposed to EUV.

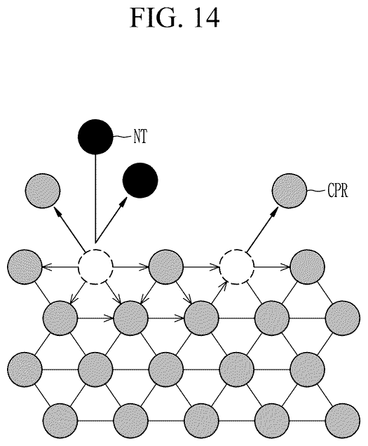

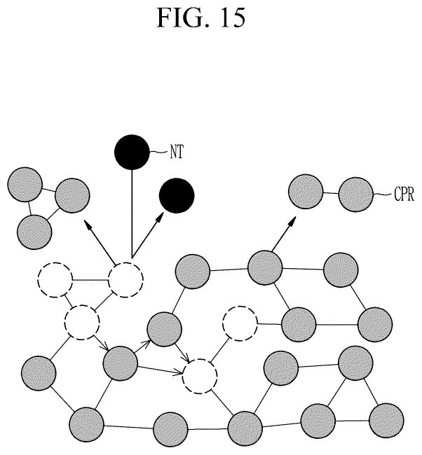

FIG. 14 and FIG. 15 show enlarged regions P2 and P3 of FIG. 12.

Referring to FIG. 14, when performing the developing process using the neutral beams containing neutrons (NT), it may be confirmed that a small amount of the photoresist (CPR) condensed by the exposure is removed due to the difference in density.

Referring to FIG. 15, when performing a developing process using the neutral beams including neutrons (NT), it may be confirmed that the etch amount of the photoresist (NPR) for the neutral beams is high because of the density difference, regarding the photoresist (NPR) not condensed by the exposure.

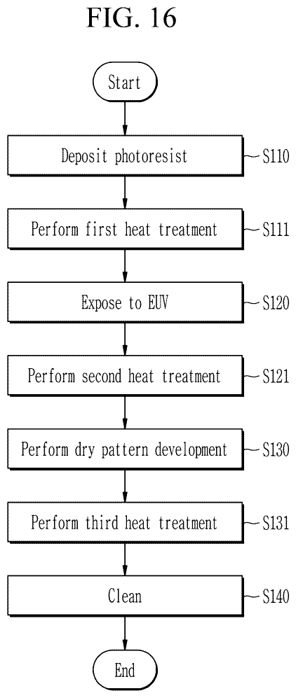

FIG. 16 shows flowchart on a substrate processing method according to another embodiment of the present disclosure.

Referring to FIG. 16, in an embodiment, the substrate processing method may include: depositing photoresist (S110); performing a first heat treatment (S111); exposing to EUV (S120); performing a second heat treatment (S121); performing a dry pattern developing (S130); and performing a third heat treatment (S131).

The first heat treatment S111 is a soft bake, which is a heat treatment performed after photoresist coating or deposition and before exposure. The first heat treatment S111 may be performed to stabilize the coating by evaporating the solvent remaining in the photoresist and to improve the sensitivity and resolution in subsequent processes.

In an embodiment, the first heat treatment S111 may be performed at a heat treatment temperature in the range of 50 to 150° C. As the first heat treatment S111 is performed in the aforementioned range, the viscosity of the photoresist may be controlled, and a basis for forming a desired pattern in the subsequent exposing and developing process may be established.

The second heat treatment S121 may correspond to the pre-exposure heat treatment, representing a post-exposure bake, and may be performed after exposure. In detail, the second heat treatment S121 may be performed to complete the chemical change formed in the photoresist and improve the quality of the exposed pattern.

In an embodiment, the second heat treatment S121 may be performed in the range of 80 to 150° C. As the second heat treatment S121 is performed in the aforementioned range, the chemical reaction generated in the exposure may be accelerated, and the clarity and accuracy of the image may be improved. In this way, the second heat treatment S121 may improve the definition of the exposure pattern, thereby enabling a high-resolution pattern transfer.

The third heat treatment S131 may be a hard bake and may be performed after the developing process. In detail, the third heat treatment S131 may enhance the durability and stability of the finally formed photoresist pattern.

In an embodiment, the third heat treatment S131 is performed in the range of 10 to 150° C. to more strongly fix the photoresist pattern to the wafer and improve the resolution of the photoresist, thereby facilitating pattern formation.

In an embodiment, a cleaning step S140 may be further included after the third heat treatment S131. The cleaning S140 may be performed as the final stage of the entire process to remove remaining materials and contamination on the substrate surface after forming the photoresist pattern.

In an embodiment, the cleaning S140 may remove the residual material and contamination by spraying a solution onto the substrate. By including the cleaning, the performance and reliability of the substrate may be optimized.

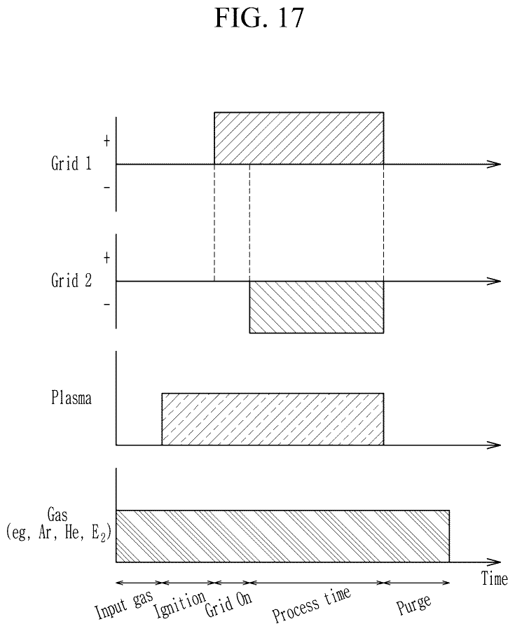

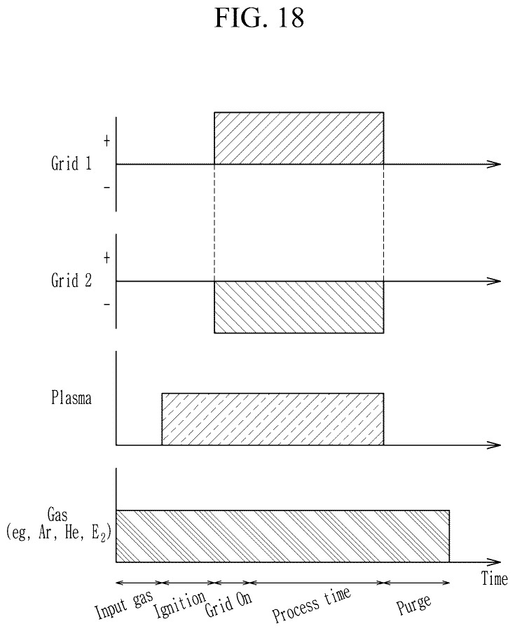

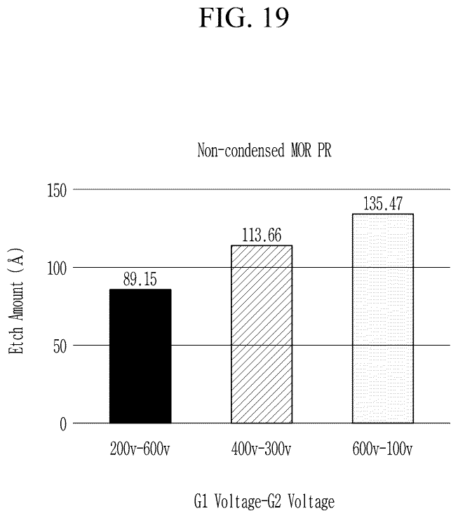

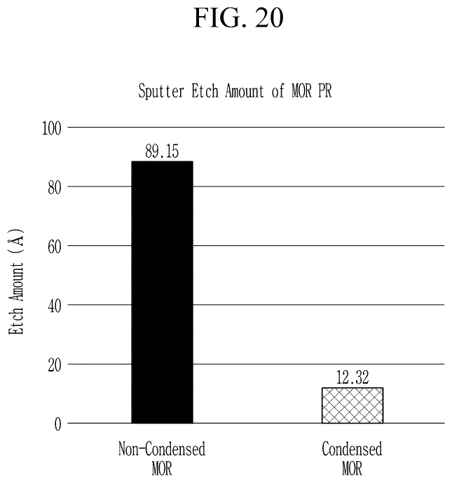

FIG. 17 to FIG. 18 show a sequence of a substrate processing method according to an embodiment of the present disclosure, and FIG. 19 and FIG. 20 show graphs on etch amounts and etch rates according to the substrate processing method.

FIG. 17 and FIG. 18 show a process for performing a developing process of a substrate processing device 400 with respect to time according to the present disclosure. In detail, the gas containing inert gas is continuously inflowed into the plasma chamber throughout the process. An ignition process for initially generating plasma is performed. The ignition process may include sufficiently ionizing particles with high density energy within the plasma chamber to spontaneously form sustainable plasma.

In detail, the ignition process may include: implanting gas into a plasma chamber, applying a power voltage as an energy source for generating plasma, and performing ionization for separating gas molecules into ions and free electrons by the energy, through which a plasma treatment region in which plasma particles such as ions and electrons move freely may be formed

The power voltage may be supplied to the first grid to accelerate the ions in the plasma, and then an additional power voltage may be supplied to the second grid to accelerate the ions. FIG. 17 shows supplying a power voltage to the first grid and then sequentially supplying a power voltage to the second grid, which is however a non-limited example, and as in FIG. 18, the power voltage may be supplied to the first grid and the second grid.

The ions, as described above, pass through the reflector to form neutrons, and the neutral beams, which are a collection of neutrons, are directed to the substrate to perform a developing process.

Referring to FIG. 19, as shown in FIG. 17, when the substrate processing device 400 is operated, the etch amount of the SnOₓ-based resist on the substrate may be confirmed. In detail, the gas flux is maintained at 20 sccm for the experiment in FIG. 19, the process pressure is maintained at 0.5 mT, the process time is controlled as 30 seconds, and the plasma is formed at 600 W.

At this time, the power voltage supplied to the first grid and the second grid is given as shown in Table 1.

TABLE 1

| | Case 1 | Case 2 | Case 3 |
|---|---|---|---|
| First grid power | +200 | +400 | +600 |
| [Voltage] | | | |
| Second grid power | −600 | −300 | −100 |
| [Voltage] | | | |
| Etch amount | 89.15 | 113.66 | 135.47 |
| (Å) | | | |

Referring to Condition 1 and FIG. 19, it may be seen that, as the amount of power voltage applied to the first grid increases, the etch amount of the metal oxide photoresist (non-condensed MOR PR) not exposed during the EUV exposure increases. Through this, it is confirmed that the amount of photoresist to be removed by the energy of the neutrons is controlled by controlling the amount of power voltage of the first grid and second grid.

FIG. 20 shows the etch rate difference between the exposed and non-exposure areas for neutral beams when the substrate processing device 400 is operated as in FIG. 17.

Referring to FIG. 20, when the Sn-based metal oxide resist is subjected to the EUV exposure, it is confirmed that the density increases in the exposed area by forming M-O-M (metal-oxygen-metal) bonds. In contrast, the non-exposure area may have a lower density because the bonding is not performed, compared to the exposed area. When the substrate processing device 400 is performed as in Case 1 of Table 1, it is confirmed that the sputter etch rates of the exposed and non-exposed areas become different due to the difference in density, resulting in selectivity.

The present disclosure is not limited to the embodiments and may be produced in various forms, and it will be understood by those skilled in the art to which the present disclosure pertains that embodiments of the present disclosure may be implemented in other specific forms without modifying the technical spirit or essential features of the present disclosure. Therefore, it should be understood that the aforementioned embodiments are illustrative in terms of all aspects and are not limited.

What is claimed is:

1. A substrate processing device comprising:
a plasma chamber;
a power voltage source arranged in the plasma chamber for generating plasma;
a process chamber defining a processing region for processing a substrate, and arranged below the plasma chamber;
a grid structure arranged between the process chamber and the plasma chamber for receiving the plasma and supplying ions or radicals; and
a reflector for forming neutrons from the ions or the radicals and supplying the neutrons to the substrate.

2. The substrate processing device of claim 1, wherein
the grid structure includes
a first grid arranged near the plasma chamber, and
a second grid arranged below the first grid.

3. The substrate processing device of claim 2, wherein
a gap ratio of a first gap between the first grid and the second grid to a second gap between the second grid and the reflector is 1:3 to 1:6.

4. The substrate processing device of claim 2, wherein
a positive voltage is supplied to the first grid, and
a negative voltage is supplied to the second grid.

5. The substrate processing device of claim 2, wherein
the grid structure further includes at least one third grid arranged below the second grid, and
wherein the third grid is grounded.

6. The substrate processing device of claim 1, further comprising:
a residual gas analyzer arranged near an outside wall of the process chamber.

7. The substrate processing device of claim 2, wherein
the first grid and the second grid each respectively include holes, and
the ions or the radicals pass through the holes and are provided to the reflector.

8. The substrate processing device of claim 1, wherein
the reflector includes at least one of a slit type and a hole type.

9. The substrate processing device of claim 1, wherein
the substrate is arranged on a substrate supporting unit, and
the substrate supporting unit is connected to a heating member.

10. The substrate processing device of claim 1, further comprising:
a gas inlet arranged on an upper portion of the plasma chamber for introducing a process gas to the plasma chamber.

11. The substrate processing device of claim 1, further comprising:
a discharge pipe connected to the process chamber for discharging neutrons in the process chamber,
wherein the discharge pipe is connected to a pumping system.

12. A substrate processing device comprising:
a plasma chamber;
a power voltage source arranged in the plasma chamber for generating plasma;
a process chamber defining a processing region for processing a substrate, and arranged below the plasma chamber;
a grid structure arranged between the process chamber and the plasma chamber for receiving the plasma and supplying ions or radicals; and
a reflector for forming neutrons from the ions or the radicals and supplying the neutrons to the substrate,
wherein the grid structure includes a first grid arranged near the plasma chamber and a second grid arranged below the first grid, and
the first grid is configured to receive a higher voltage than the second grid.

13. The substrate processing device of claim 12, wherein
a positive voltage is supplied to the first grid, and a negative voltage is supplied to the second grid.

14. The substrate processing device of claim 12, wherein
the voltage supplied to the first grid and the voltage supplied to the second grid satisfy Condition 1:
$$\vert {G}_{1} - {G}_{2} \vert \geq 600 V \qquad 〈 Condition 1 〉$$
wherein, G₁ and G₂ represent the voltage supplied to the first grid and the voltage supplied to the second grid, and |G₁-G₂| represents an absolute value of a difference value between the voltages G₁ and G₂.

15. The substrate processing device of claim 12, wherein
the voltage supplied to the first grid is 100 to 1000 V.

16. The substrate processing device of claim 12, wherein
the voltage supplied to the second grid is −1000 to −100 V.

17. The substrate processing device of claim 12, wherein
the substrate is arranged on a substrate supporting unit,
the substrate supporting unit is connected to a heating member, and
the heating member controls a temperature of the substrate in a range of 10 to 150° C.

18. The substrate processing device of claim 12, further comprising:
a gas inlet arranged on an upper portion of the plasma chamber for introducing a process gas in the plasma chamber, and
the process gas is hydrogen (H₂), argon (Ar), helium (He), nitrogen (N₂), halogen, or any combination thereof.

19. The substrate processing device of claim 12, wherein
an absolute value of the voltage supplied to the first grid is greater than an absolute value of the voltage supplied to the second grid.

20. A substrate processing device comprising:
a plasma chamber;
a power voltage source arranged in the plasma chamber for generating plasma;
a substrate supporting unit for supporting a substrate;
a process chamber defining a processing region for processing the substrate, and arranged below the plasma chamber;
a grid structure arranged between the process chamber and the plasma chamber for receiving the plasma and supplying ions or radicals, and including a first grid arranged near the plasma chamber and a second grid arranged below the first grid;
a reflector for forming neutrons from the ions or the radicals and supplying the neutrons to the substrate; and
a heating member connected to the substrate supporting unit for heating the substrate,
wherein the voltage supplied to the first grid and the voltage supplied to the second grid satisfy Condition 1:
$$\vert {G}_{1} - {G}_{2} \vert \geq 600 V \qquad 〈 Condition 1 〉$$
wherein, G₁ and G₂ represent the voltage supplied to the first grid and the voltage supplied to the second grid, and |G₁-G₂| represents an absolute value of a difference value between the voltages G₁ and G₂.
